(19) United States
(12) Patent Application Publication
(10) Pub. No.: US 2020/0089305 A1
(43) Pub. Date: Mar. 19, 2020

(54) OPERATION INPUT DEVICE

(71) Applicant: Yazaki Corporation, Tokyo (JP)

(72) Inventors: Akihiro Ohata, Shizuoka (JP); Tetsuro Takasaki, Shizuoka (JP)

(21) Appl. No.: 16/565,442

(22) Filed: Sep. 9, 2019

(30) Foreign Application Priority Data
Sep. 14, 2018 (JP) 2018-172172

(51) Int. Cl. G06F 1/3231; G06F 3/042; B60K 35/00

(52) U.S. Cl. CPC G06F 1/3231; G06F 3/0421; B60K 35/00; B60Y 2400/3086; B60Y 2400/301; B60K 2370/139; B60K 2370/1446

(57) ABSTRACT

An operation input device includes a detection unit configured to sense a detection value changing according to a distance to a detection target object and a controller configured to detect input operation in a case where the detection value is equal to or greater than a first threshold. The controller stands by in a sleep mode in which a power consumption is reduced as compared to a normal standby mode in a case where the detection value is less than a second threshold, which is smaller than the first threshold, as a threshold indicating that the distance between the detection target object and the detection unit is equal to or shorter than a second distance longer than the first distance, and stands by in the normal standby mode in a case where the detection value is equal to or greater than the second threshold.

### CROSS-REFERENCE TO RELATED APPLICATION(S)

The present application claims priority to and incorporates by reference the entire contents of Japanese Patent Application No. 2018-172172 filed in Japan on Sep. 14, 2018.

### BACKGROUND OF THE INVENTION

### 1. Field of the Invention

The present invention relates to an operation input device.

### 2. Description of the Related Art

Operation switches for performing operation of equipment provided in, e.g., a compartment of an automobile are arranged in the compartment. Among these operation switches, there are operation switches for which contactless input operation can be performed (e.g., Japanese Patent Application Laid-open No. 2017-107782).

In an operation input device such as the operation switch, a control signal corresponding to operation contents is transmitted to each type of equipment after the input operation has been sensed, and therefore, a control integrated circuit (IC) configured to control the operation input device itself is constantly in an activated state. Thus, the operation input device is, even during standby for the input operation, in a state in which power of the IC is consumed. Such a power consumption during the standby can be reduced when a so-called sleep state for reducing a power supply to the IC is brought, for example. However, in a case where the operation input device is brought into the sleep state, the IC is activated after the user's input operation has been sensed, and the control signal is transmitted to each type of equipment to control operation of each type of equipment. Thus, there is a time lag until the equipment is actually operated after a user has performed the input operation.

### SUMMARY OF THE INVENTION

The present invention has been made in view of the above-described point, and is intended to provide an operation input device configured so that a time lag in operation of equipment in response to input operation can be reduced while a power consumption can be reduced.

In order to solve the above mentioned problem and achieve the object, an operation input device according to one aspect of the present invention includes a detection unit configured to sense a detection value changing according to a distance to a detection target object; and a controller configured to detect input operation in a case where the detection value is equal to or greater than a first threshold indicating that a distance between the detection target object and the detection unit is equal to or shorter than a first distance, wherein the controller stands by in a sleep mode in which a power consumption is reduced as compared to a normal standby mode in a case where the detection value is less than a second threshold, which is smaller than the first threshold, as a threshold indicating that the distance between the detection target object and the detection unit is equal to or shorter than a second distance longer than the first distance, and stands by in the normal standby mode in a case where the detection value is equal to or greater than the second threshold.

According to another aspect of the present invention, in the operation input device, it is preferable that the detection unit is a capacitance sensor, and the detection value is an electric field intensity sensed by the sensor.

According to still another aspect of the present invention, in the operation input device, it is preferable that the operation input device includes a projection unit configured to irradiate detection light, wherein the detection unit is a light receiving unit configured to receive the detection light reflected on the detection target object, and the detection value is an angle of the detection light reflected on the detection target object.

According to still another aspect of the present invention, in the operation input device, it is preferable that the controller reduces, in the sleep mode, a frequency of sensing the detection value or a frequency of comparing the detection value with the first and second thresholds as compared to the normal standby mode, thereby reducing the power consumption in the sleep mode than that in the normal standby mode.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view of an illuminating lamp to which an operation input device is applied;

FIG. 2 is an exploded perspective view of the illuminating lamp illustrated in FIG. 1;

FIG. 3 is a plan view of the illuminating lamp illustrated in FIG. 1;

FIG. 4 is an A-A sectional view of FIG. 1;

FIG. 5 is a block diagram of a main configuration of the operation input device according to the embodiment;

FIG. 6 is a flowchart of processing steps for input operation for the operation input device according to the embodiment;

FIG. 7 is a schematic view when the input operation is performed for the operation input device; and

FIG. 8 illustrates a variation of the operation input device according to the embodiment, and is a view for describing the case of using detection light for detection of a distance to a detection target object.

### DETAILED DESCRIPTION OF THE PREFERRED EMBODIMENTS

A mode (an embodiment) for carrying out the present invention will be described in detail with reference to the drawings. The present invention is not limited by contents described in the embodiment below. Moreover, components described below include components easily arrived by those skilled in the art and substantially-identical components. Further, configurations described below may be combined as necessary. Moreover, various omissions, replacements, or changes can be made to the configurations without departing from the gist of the present invention.

### Embodiment

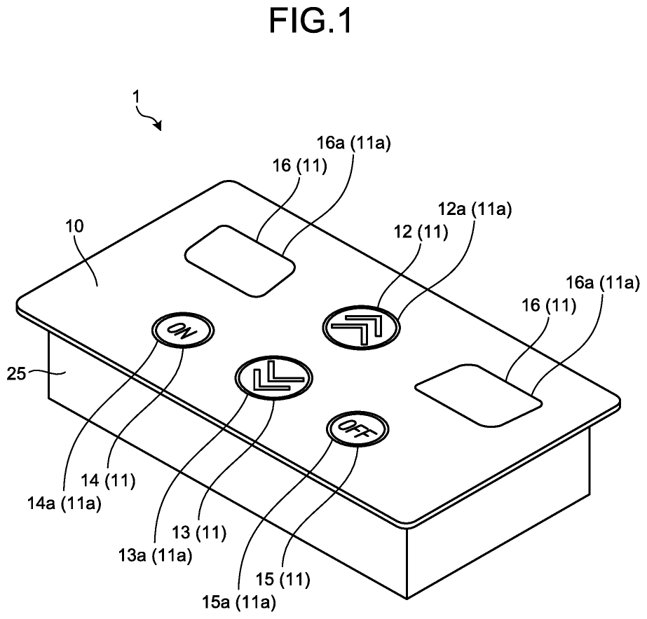

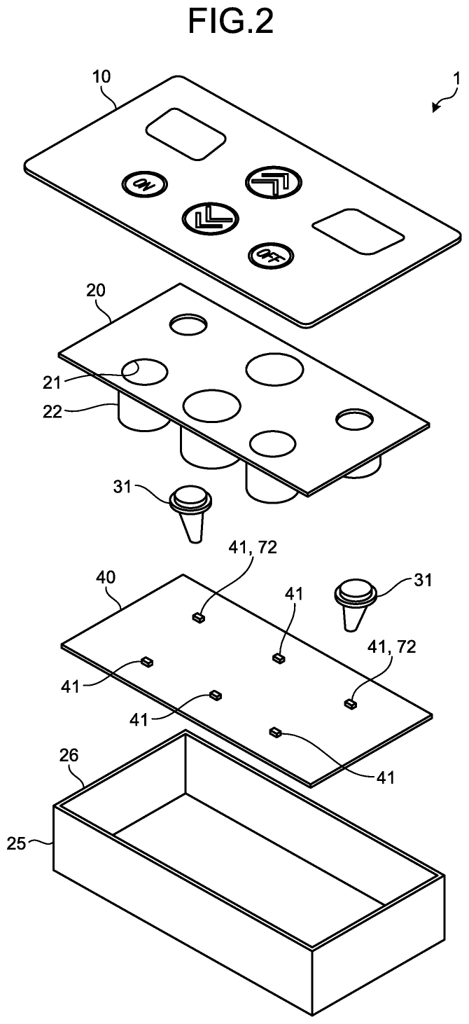

An operation input device according to the embodiment will be described. FIG. 1 is a perspective view of an illuminating lamp 1 to which an operation input device 50 is applied. FIG. 2 is an exploded perspective view of the illuminating lamp 1 illustrated in FIG. 1. The illuminating lamp 1 is, for example, arranged on a ceiling surface inside a compartment of an automobile (not illustrated), and is arranged at such a position that a driver of the automobile or a passenger on a passenger seat can operate the illuminating lamp 1 with the driver or the passenger sitting on a seat. The illuminating lamp 1 includes a lens 10, an inner housing 20, an outer housing 25, and a substrate 40. Of these components, the outer housing 25 is formed in a substantially rectangular parallelepiped box shape including an opening 26 formed such that one of six surfaces opens.

The inner housing 20 and the substrate 40 are formed in such a shape that projection shapes from an opening 26 side of the outer housing 25 are equivalent to the shape of the opening 26 and are slightly smaller than the opening 26. Moreover, the inner housing 20 and the substrate 40 are arranged overlapping with each other in the outer housing 25 in such an arrangement form that the inner housing 20 is positioned on the opening 26 side of the outer housing 25 and the substrate 40 is positioned on a closed surface side of the outer housing 25 opposite to the opening 26.

Further, multiple light emitting diodes (LEDs) 41 used as light emitting units are arranged on a surface of the substrate 40 on a side on which the inner housing 20 is positioned. An opening hole 21 penetrating the inner housing 20 in a thickness direction thereof is formed at a position of the inner housing 20 facing each of the multiple LEDs 41 arranged on the substrate 40. In addition, a prism 31 as a light guide member including a transparent member such as transparent resin is arranged between an illuminating LED 72 as one of the multiple LEDs 41 and the inner housing 20.

The lens 10 is formed in a substantially rectangular plate shape equivalent to the shape of the opening 26 of the outer housing 25. The lens 10 engages with the opening 26 of the outer housing 25 in a state in which the inner housing 20 and the substrate 40 are arranged inside the outer housing 25, and therefore, can close the opening 26.

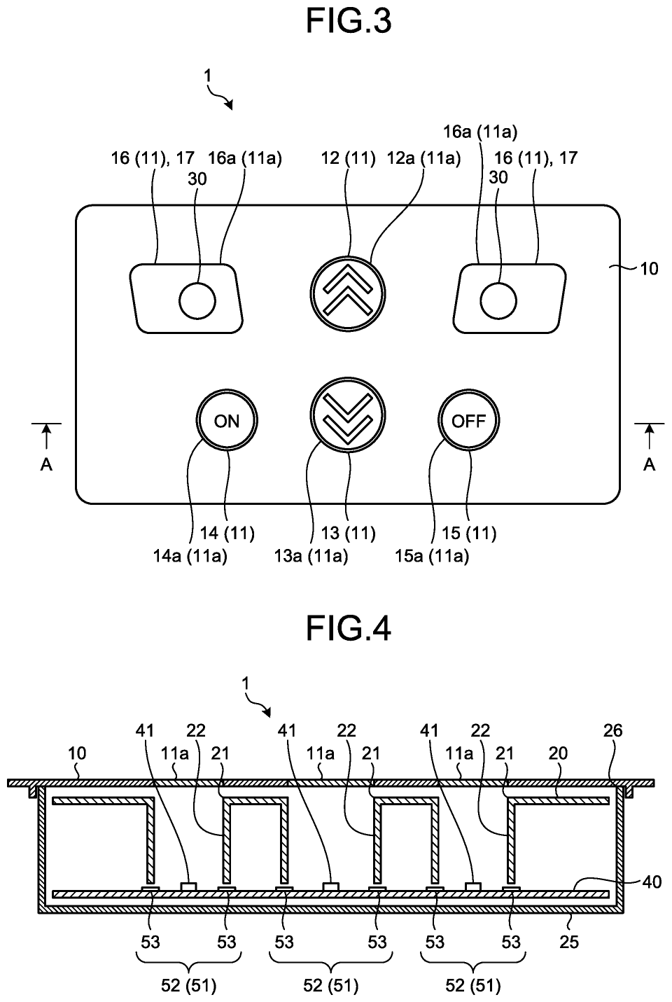

FIG. 3 is a plan view of the illuminating lamp 1 illustrated in FIG. 1. Multiple switch regions 11a are arranged on the lens 10. Portions of the lens 10 where the switch regions 11a are positioned are configured such that light transmission is allowed, and other portions than the switch regions 11a are configured such that light transmission is not allowed. In the present embodiment, a sunroof open switch region 12a, a sunroof close switch region 13a, an illumination ON switch region 14a, an illumination OFF switch region 15a, and spot illumination switch regions 16a are provided as the switch regions 11a.

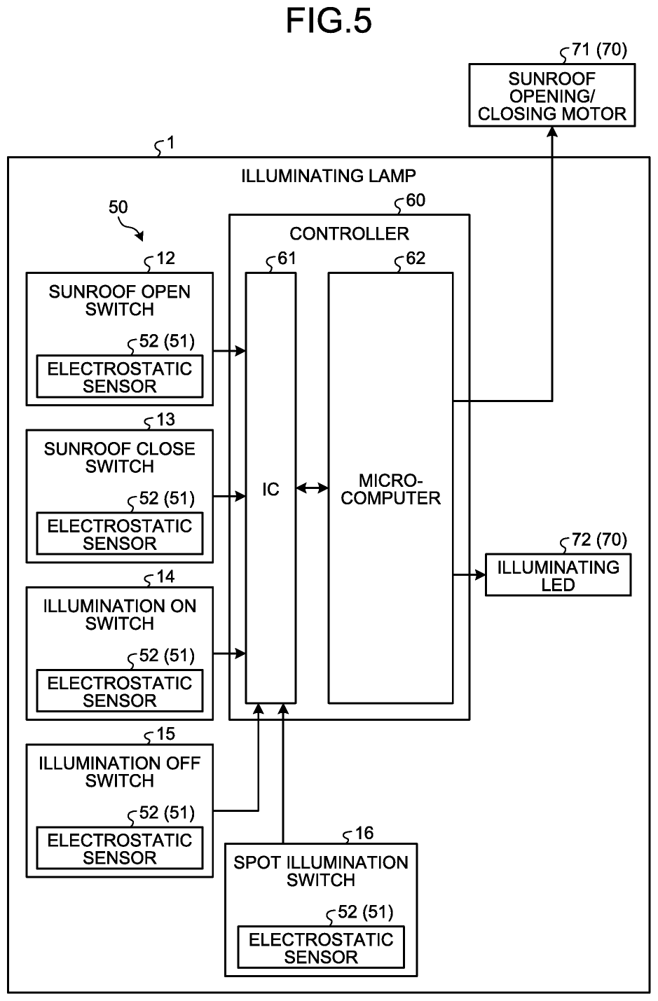

These switch regions 11a each form separate switches 11 by later-described electrostatic sensors 52 (see FIGS. 4 and 5). That is, the sunroof open switch region 12a forms a sunroof open switch 12 by the electrostatic sensor 52. The sunroof close switch region 13a forms a sunroof close switch 13 by the electrostatic sensor 52. The illumination ON switch region 14a forms an illumination ON switch 14 by the electrostatic sensor 52. The illumination OFF switch region 15a forms an illumination OFF switch 15 by the electrostatic sensor 52. The spot illumination switch regions 16a form spot illumination switches 16 by the electrostatic sensors 52.

Of the switches 11 formed by the switch regions 11a and the electrostatic sensors 52, the sunroof open switch 12 and the sunroof close switch 13 are the switches 11 for opening/closing a sunroof (not illustrated) provided at the automobile. That is, the sunroof open switch 12 is the switch 11 for opening the sunroof, and the sunroof close switch 13 is the switch 11 for closing the sunroof. In the sunroof open switch region 12a of the sunroof open switch 12 and the sunroof close switch region 13a of the sunroof close switch 13, a movement direction of the sunroof in operation of the switch 11 is displayed using a pattern such as an arrow so that operation of the sunroof can be easily recognized in operation of each switch 11.

The illumination ON switch 14 and the illumination OFF switch 15 are the switches 11 for spot illuminations 30 provided at the illuminating lamp 1. The illuminating lamp 1 includes two spot illuminations 30, and two spot illuminations 30 are, at the illuminating lamp 1, each arranged at a position closer to a driver seat and a position closer to the passenger seat in the case of arranging the illuminating lamp 1 inside the compartment of the automobile so that a driver seat side and a passenger seat side can be irradiated, for example. The spot illumination 30 includes the illuminating LED 72 (see FIG. 2) and the prism 31 (see FIG. 2) arranged on the substrate 40 (see FIG. 2), and spot light transmission portions 17 are provided at position corresponding to arrangement positions of the illuminating LEDs 72 and the prisms 31 at the lens 10. The spot light transmission portion 17 is in a transparent window shape, and light emitted from the illuminating LED 72 and transmitted through the prism 31 can be transmitted through the spot light transmission portion 17. The illumination ON switch 14 is the switch 11 for turning on any of these two spot illuminations 30 configured as described above, and the illumination OFF switch 15 is the switch 11 for turning off any of two spot illuminations 30.

The spot illumination switches 16 are also the switches 11 for the spot illuminations 30. Two spot illumination switches 16 are provided corresponding to two spot illuminations 30, and two spot illumination switch regions 16a forming two spot illumination switches 16 are each positioned on the spot illuminations 30. That is, the positions of the spot light transmission portions 17 also serve as the spot illumination switch regions 16a. Unlike the illumination ON switch 14 and the illumination OFF switch 15, the spot illumination switches 16 can independently turn on or off the spot illuminations 30 on a side on which the spot illumination switch regions 16a are positioned. When the spot illumination switch 16 is operated while a corresponding one of the spot illuminations 30 is OFF, the spot illumination switch 16 can turn on the spot illumination 30. When the spot illumination switch 16 is operated while a corresponding one of the spot illuminations 30 is ON, the spot illumination switch 16 can turn off the spot illumination 30.

FIG. 4 is an A-A sectional view of FIG. 1. The multiple LEDs 41 arranged on the substrate 40 are arranged at positions corresponding to the positions of the multiple switch regions 11a as viewed from a lens 10 side. Thus, the multiple opening holes 21 formed at the inner housing 20 are also formed at positions corresponding to the positions of the multiple switch regions 11a as viewed from the lens 10 side, i.e., each opening hole 21 is formed at a position facing the switch region 11a. Moreover, at the inner housing 20, a light guide portion 22 is provided on a side facing the substrate 40 at a position provided with each opening hole 21. The light guide portion 22 is formed in a substantially cylindrical shape. One end side of a cylinder communicates with the opening hole 21, and the other end side of the cylinder is arranged facing the position of the LED 41. Thus, when light emitted from the LED 41 is emitted from the opening hole 21 to the lens 10 side through the inside of the light guide portion 22, the light guide portion 22 and the opening hole 21 can, when the LED 41 is ON, guide the light from the LED 41 to the switch region 11a of the lens 10. Since the portions of the lens 10 where the switch regions 11a are positioned are configured such that light transmission is allowed, the switch region 11a of the lens 10 emits light by the light irradiated from the LED 41 when the LED 41 is ON.

The illuminating lamp 1 configured as described above has the operation input device 50. FIG. 5 is a block diagram of a main configuration of the operation input device 50 according to the embodiment. The operation input device 50 includes detection units 51 configured to sense detection values changing according to a distance to a detection target object such as a human hand, and a controller 60 configured to control operation equipment 70. In the present embodiment, the electrostatic sensor 52 as a capacitance sensor is used for the detection unit 51. Thus, the detection value changing according to the distance from the detection unit 51 to the detection target object and sensed by the detection unit 51 is an electric field intensity sensed by the electrostatic sensor 52. The electric field intensity sensed by the electrostatic sensor 52 increases as the distance from the electrostatic sensor 52 to the detection target object decreases. That is, the detection value sensed by the detection unit 51 increases as the distance between the detection unit 51 and the detection target object decreases, and decreases as the distance between the detection unit 51 and the detection target object increases.

The multiple electrostatic sensors 52 as the detection units 51 are provided corresponding to the multiple switches 11. That is, the electrostatic sensor 52 for the sunroof open switch 12, the electrostatic sensor 52 for the sunroof close switch 13, the electrostatic sensor 52 for the illumination ON switch 14, the electrostatic sensor 52 for the illumination OFF switch 15, and the electrostatic sensors 52 for the spot illumination switches 16 are provided as the electrostatic sensors 52.

Each electrostatic sensor 52 includes a pair of electrodes 53 (see FIG. 4). Specifically, the electrostatic sensor 52 generates an electric field by means of the pair of electrodes 53 separated from each other so that a change in the electric field intensity between the electrodes 53 can be sensed. The pair of electrodes 53 provided at the electrostatic sensor 52 is arranged on the substrate 40. The pair of electrodes 53 provided at each of the multiple electrostatic sensors 52 is arranged in the vicinity of the LED 41 corresponding to the switch 11 corresponding to the electrostatic sensor 52. Specifically, each electrode 53 of the electrostatic sensor 52 is arranged at a position facing a substrate-40-side end portion of the light guide portion 22 of the inner housing 20 on the substrate 40.

For example, the pair of electrodes 53 provided at the electrostatic sensor 52 for the sunroof open switch 12 is arranged at positions facing substrate-40-side end portions of the light guide portion 22 of the inner housing 20 corresponding to the LED 41 for the sunroof open switch 12. Thus, when the illuminating lamp 1 is viewed from the lens 10 side, the electrostatic sensor 52 is arranged at such a position that the electrostatic sensor 52 corresponding to each switch 11 overlaps with the position of the switch region 11a corresponding to the switch 11 on the lens 10 or overlaps with a position in the vicinity of the switch region 11a on the lens 10.

The controller 60 is arranged on the substrate 40, and has a central processing unit (CPU) configured to perform arithmetic processing and a random access memory (RAM) and a read only memory (ROM) functioning as memories configured to store various types of information, for example. Some or all of the functions of the controller 60 are implemented in such a manner that an application program held in the ROM is loaded into the RAM and executed by the CPU to read data from the RAM or the ROM and write data in the RAM or the ROM.

The controller 60 has an IC 61 and a microcomputer 62 functionally separated from each other. Of these components, the IC 61 is connected to the electrostatic sensors 52 to acquire the detection values of the electrostatic sensors 52, and the microcomputer 62 is connected to the operation equipment 70 to control operation of the operation equipment 70. Operation of the operation equipment 70 described herein includes not only actual behavior but also a state change by electric action, such as ON/OFF of the LED 41. In the present embodiment, a sunroof opening/closing motor 71 and the illuminating LED 72 are applied as the operation equipment 70. The microcomputer 62 is electrically connected to the IC 61, and controls the operation equipment 70 based on the detection value sensed by the electrostatic sensor 52 and acquired by the IC 61. The IC 61 and the microcomputer 62 may be configured integrally, or may be configured separately and electrically connected to each other.

The controller 60 stores two thresholds set for the detection value of the electrostatic sensor 52. A first threshold as one of two thresholds is the detection value of the electrostatic sensor 52 when the distance between the detection target object such as the human hand and the electrostatic sensor 52 is a first distance as such a distance that it can be determined that input operation has been performed for the switch 11. Since the first distance is such a distance that it can be determined that the detection target object has contacted the lens 10, a distance from the lens 10 is set as a distance of about several mm. Moreover, a second threshold as the other one of two thresholds is a smaller value than the first threshold, and is the detection value of the electrostatic sensor 52 when the distance between the detection target object and the electrostatic sensor 52 is a second distance longer than the first distance by a predetermined distance. The second distance is set as such a distance that the distance from the lens 10 is about 100 mm.

That is, the first threshold is an electric field intensity sensed by the electrostatic sensor 52 when the distance between the detection target object and the electrostatic sensor 52 is the first distance, and the second threshold is an electric field intensity sensed by the electrostatic sensor 52 when the distance between the detection target object and the electrostatic sensor 52 is the second distance. The electric field intensity sensed by the electrostatic sensor 52 increases as the distance between the detection target object and the electrostatic sensor 52 decreases, and therefore, the first threshold is greater than the second threshold.

Moreover, the controller 60 has, as modes for controlling the operation equipment 70 according to the input operation for the switch 11, a normal standby mode and a sleep mode having a lower power consumption than that of the normal standby mode. Of these modes, the sleep mode is a mode for reducing the frequency of sensing the detection value or the frequency of comparing the detection value with the first and second thresholds as compared to the normal standby mode. Thus, in the sleep mode, the power consumption can be decreased as compared to the power consumption of the normal standby mode. The controller 60 switches the mode between the normal standby mode and the sleep mode according to the electric field intensity sensed by the electrostatic sensor 52.

The operation input device 50 according to the present embodiment has the following configuration, and action thereof will be described below. The illuminating lamp 1 including the operation input device 50 has the multiple LEDs 41, but in a normal state, the LEDs 41 are not ON. When a switch (not illustrated) for switching lamps of the automobile is switched to a position for turning on a width light or a headlight, other LEDs 41 than the illuminating LEDs 72 are turned on. When the LEDs 41 are turned on, light from the LEDs 41 passes through the light guide portions 22 and the opening holes 21 of the inner housing 20, and is transmitted through the switch regions 11a of the lens 10. Accordingly, light is emitted from other switch regions 11a of the lens 10 than the spot illumination switches 16. Thus, even in, e.g., a dark state in the compartment of the automobile during the night, the passengers of the automobile can recognize the positions of the switch regions 11a provided at the illuminating lamp 1.

When the input operation is performed for the illuminating lamp 1, the passenger of the automobile touches the switch region 11a provided at the illuminating lamp 1 with a hand or approaches one's hand to the switch region 11a to perform the input operation for the switch 11. For example, in the case of turning on the spot illumination 30, the illumination ON switch region 14a provided at the illumination ON switch 14 or the spot illumination switch region 16a provided at the spot illumination switch 16 is touched by a hand. When the illumination ON switch region 14a or the spot illumination switch region 16a is touched by the hand for the input operation for the illumination ON switch 14 or the spot illumination switch 16, the illuminating LED 72 is turned on. When the illuminating LED 72 is turned on, light from the illuminating LED 72 passes through the light guide portion 22 and the opening hole 21 of the inner housing 20, and further passes through the prism 31 such that a light travelling direction is adjusted. Then, the light is irradiated from the spot light transmission portion 17 of the lens 10. Thus, the spot illumination 30 is turned on. The illumination ON switch 14 and the illumination OFF switch 15 can switch ON/OFF of both of two spot illuminations 30, and the spot illumination switches 16 can switch ON/OFF of the spot illuminations 30 on a side on which the spot illumination switches 16 are positioned. When the input operation is performed while the spot illumination 30 is ON, the spot illumination switch 16 can turn off the spot illumination 30. When the input operation is performed while the spot illumination 30 is OFF, the spot illumination switch 16 can turn on the spot illumination 30.

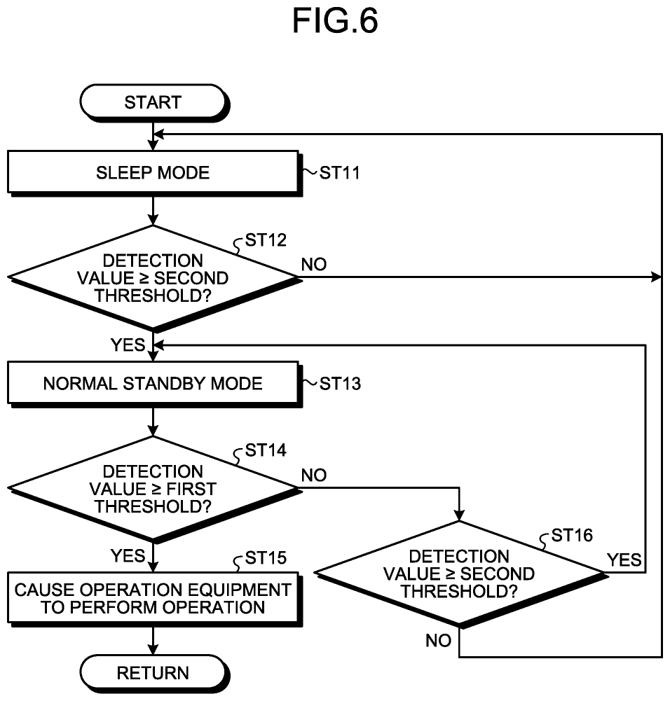

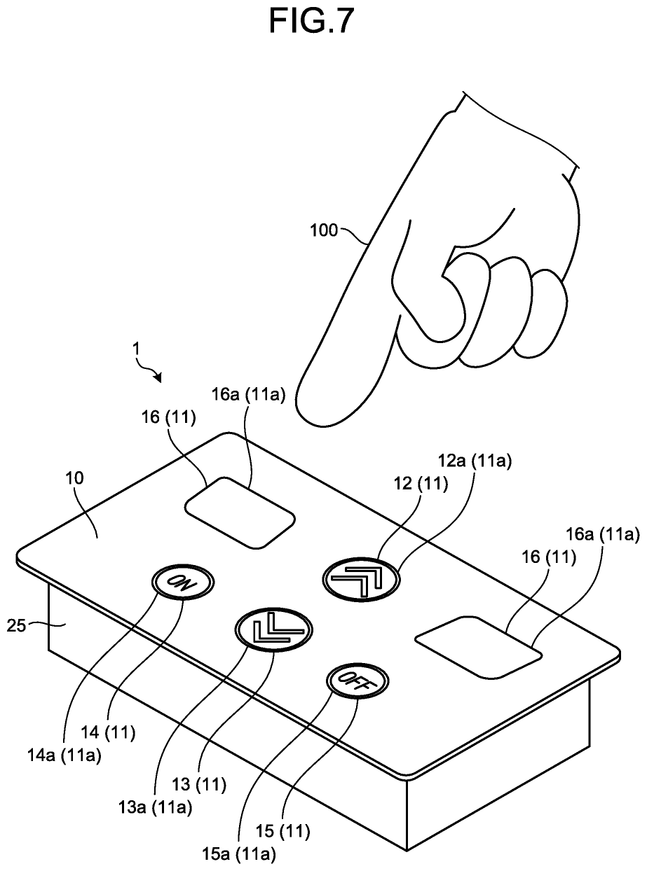

FIG. 6 is a flowchart of processing steps for the input operation for the operation input device 50 according to the embodiment. FIG. 7 is a schematic view when the input operation is performed for the operation input device 50. The operation input device 50 provided at the illuminating lamp 1 stands by, in the normal state, in the sleep mode for reducing the frequency of sensing the detection value of the electrostatic sensor 52 or the frequency of comparing the detection value with the first and second thresholds (Step ST11). During standby in the sleep mode, when the detection value sensed by the electrostatic sensor 52 changes, the controller 60 determines whether or not the detection value is equal to or greater than the second threshold (Step ST12). That is, it is determined whether or not the electric field intensity sensed by the electrostatic sensor 52 is equal to or higher than the second threshold.

In a case where determination that the detection value is less than the second threshold is made upon such determination (Step ST12, determination as No), the standby in the sleep mode is continued (Step ST11). That is, in a case where the electric field intensity sensed by the electrostatic sensor 52 is lower than the second threshold, it indicates that a human hand 100 as the detection target object performing the input operation for the operation input device 50 is greatly apart from the lens 10 and is greatly apart from the switch 11. This case indicates that the input operation is not promptly performed for the switch 11, and therefore, the standby in the sleep mode is continued.

On the other hand, in a case where it is determined that the detection value sensed by the electrostatic sensor 52 is equal to or greater than the second threshold (Step ST12, determination as Yes), the controller 60 transitions to the normal standby mode (Step ST13). That is, the second threshold is the detection value threshold when the distance between the hand 100 and the electrostatic sensor 52 is the second distance longer than the first distance, and therefore, in a case where the electric field intensity as the detection value of the electrostatic sensor 52 is equal to or higher than the second threshold, it indicates that the distance between the hand 100 and the electrostatic sensor 52 is equal to or shorter than the second distance. This case indicates that the human hand 100 performing the input operation is close to the lens 10 and is close to the switch region 11a, and indicates that there is a high probability that the input operation is to be performed for the switch 11. Thus, the controller 60 wakes up from the sleep mode, and stands by in the normal standby mode. In this manner, the frequency of sensing the detection value of the electrostatic sensor 52 or the frequency of comparing the detection value with the first and second thresholds is increased as compared to the sleep mode, and when the input operation is performed for the switch 11, the input operation can be sensed within a short period of time and the operation equipment 70 can be operated.

During standby in the normal standby mode, when the detection value sensed by the electrostatic sensor 52 changes, the controller 60 determines whether or not the detection value is equal to or greater than the first threshold (Step ST14). That is, it is determined whether or not the electric field intensity sensed by the electrostatic sensor 52 is equal to or greater than the first threshold. In a case where determination that the detection value is equal to or greater than the first threshold is made upon such determination (Step ST14, determination as Yes), the operation equipment 70 performs operation (Step ST15). That is, in a case where the detection value sensed by the electrostatic sensor 52 is equal to or greater than the first threshold, it indicates that the distance between the human hand 100 performing the input operation and the electrostatic sensor 52 is equal to or shorter than the first distance, and indicates that the hand 100 is close to contact the lens 10. In this case, the controller 60 causes the operation equipment 70 corresponding to the switch 11 having the electrostatic sensor 52 to perform operation corresponding to the switch 11. That is, in a case where it is determined that the detection value is equal to or greater than the first threshold, the controller 60 detects that the input operation has been performed for the switch 11, and causes the operation equipment 70 to perform operation.

For example, in a case where the electric field intensity sensed by the electrostatic sensor 52 provided at the sunroof open switch 12 is equal to or higher than the first threshold, it indicates that the hand 100 contacts the position of the sunroof open switch region 12a on the lens 10. Thus, in this case, the controller 60 operates the sunroof opening/closing motor 71 in the direction of opening the sunroof. As descried above, in a case where the detection value sensed by the electrostatic sensor 52 is equal to or greater than the first threshold, the controller 60 causes the operation equipment 70 corresponding to the switch 11 having the electrostatic sensor 52 to perform operation corresponding to the switch 11.

On the other hand, in a case where the detection value of the electrostatic sensor 52 sensed during the standby in the normal standby mode is determined as being less than the first threshold (Step ST14, determination as No), it is again determined whether or not the detection value sensed by the electrostatic sensor 52 is equal to or greater than the second threshold (Step ST16). In a case where determination that the detection value is equal to or greater than the second threshold is made upon such determination (Step ST16, determination as Yes), the controller 60 continues the standby in the normal standby mode.

On the other hand, in a case where it is determined that the detection value sensed by the electrostatic sensor 52 is less than the second threshold (Step ST16, determination as No), the controller 60 transitions to the sleep mode (Step ST11). That is, in a case where the electric field intensity sensed by the electrostatic sensor 52 is less than the second threshold, it indicates that the hand 100 is greatly apart from the switch 11, and indicates that the input operation is not promptly performed for the switch 11. Thus, in this case, the mode transitions to the sleep mode, and, e.g., the frequency of sensing the electric field intensity is reduced.

The operation input device 50 according to the above-described embodiment sets the first threshold and the second threshold for the detection value of the electrostatic sensor 52. In a case where the detection value of the electrostatic sensor 52 is less than the second threshold, the operation input device 50 stands by in the sleep mode for reducing the power consumption as compared to the normal standby mode. Thus, the power consumption can be reduced. Moreover, in a case where the detection value of the electrostatic sensor 52 is equal to or greater than the second threshold, the operation input device 50 stands by in the normal standby mode. In a case where the detection value is equal to or greater than the first threshold, the operation input device 50 causes the operation equipment 70 to perform operation. Thus, in a case where the human hand 100 performing the input operation approaches the switch 11 to a certain extent, a state in which the input operation for the switch 11 can be promptly sensed can be brought. Thus, when the input operation is actually performed for the switch 11, the operation equipment 70 can promptly perform operation. As a result, a time lag in operation of the equipment in response to the input operation can be reduced while the power consumption can be reduced.

Moreover, the detection unit 51 configured to sense the hand 100 as the detection target object is the capacitive electrostatic sensor 52, and the detection value changing according to the distance to the hand 100 is the electric field intensity sensed by the electrostatic sensor 52. Thus, the hand 100 at a position apart from the switch 11 can be more properly sensed by the electrostatic sensor 52. Thus, the normal standby mode and the sleep mode can be more properly switched from each other according to the distance from the switch 11 to the hand 100. As a result, the time lag in operation of the equipment in response to the input operation can be reduced while the power consumption can be reduced.

Further, the controller 60 reduces, in the sleep mode, the frequency of sensing the detection value or the frequency of comparing the detection value with the first and second thresholds as compared to the normal standby mode, and in this manner, the power consumption in the sleep mode is reduced. Thus, the power consumption can be reduced without influencing control of the operation equipment 70. As a result, the power consumption can be more reliably and easily reduced.

Variations

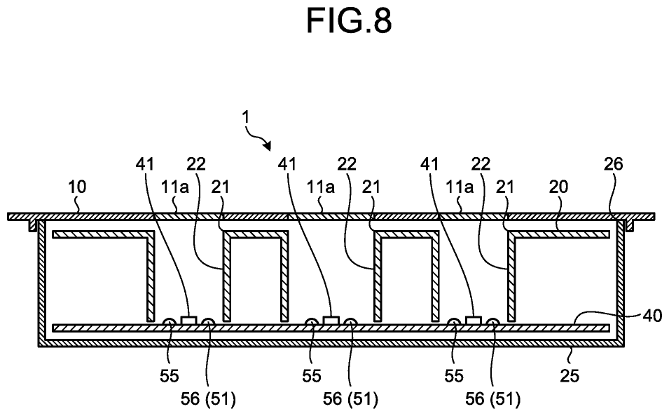

Note that in the above-described embodiment, the electrostatic sensor 52 as the capacitance sensor is used as the detection unit 51, but the detection unit 51 configured to sense the detection value changing according to the distance to the detection target object may be other sensors than the electrostatic sensor 52. FIG. 8 illustrates a variation of the operation input device 50 according the embodiment, and is a view for describing the case of using detection light for detection of the distance to the detection target object. For determination on the distance between the detection target object such as the hand 100 and the detection unit 51, a projection unit 55 configured to irradiate the detection light may be provided, and a light receiving unit 56 configured to receive the detection light reflected on the detection target object may be used as the detection unit 51 as illustrated in FIG. 8, for example. The projection unit 55 in this case irradiates infrared light as the detection light, and a position sensitive detector (PSD) is used as the light receiving unit 56 configured to receive the infrared light. Thus, a detection value detected by the light receiving unit 56 is the angle of the detection light reflected on the detection target object. That is, the infrared light irradiated from the projection unit 55 is reflected on the detection target object, and the reflected infrared light is received by the light receiving unit 56. An incident angle when the infrared light reflected on the detection target object is received by the light receiving unit 56 changes according to the distance to the detection target object.

Specifically, when the infrared light enters the light receiving unit 56, in a case where an inclination angle of an infrared light incident direction with reference to a front position of the light receiving unit 56 (0°) is the incident angle of the infrared light, the incident angle increases as the distance between the detection target object and the light receiving unit 56 decreases. The light receiving unit 56 senses the incident angle of the infrared light reflected on the detection target object, the incident angle changing according to the distance to the detection target object as described above. Moreover, the first and second thresholds set by the controller 60 are set for the incident angle. Thus, in a case where the incident angle of the infrared light sensed by the light receiving unit 56 is equal to or greater than the first threshold, the controller 60 causes the operation equipment 70 to perform operation. In a case where the incident angle is equal to or greater than the second threshold, the controller 60 stands by in the normal standby mode. In a case where the incident angle is less than the second threshold, the controller 60 stands by in the sleep mode. As described above, other sensors than the electrostatic sensor 52 may be used as the detection unit 51.

Moreover, in the above-described embodiment, the sunroof open switch 12, the sunroof close switch 13, the illumination ON switch 14, the illumination OFF switch 15, and the spot illumination switches 16 are provided as the switches 11 using the detection units 51. However, the switches 11 may be other switches. Use application of the switch 11 using the detection unit 51 is not limited.

Further, in the above-described embodiment, the operation input device 50 is used for the illuminating lamp 1 placed inside the compartment of the automobile, and may be used for other types of equipment or other devices than the illuminating lamp 1.

In addition, for the sleep mode, other techniques than the above-described technique may be used for reducing the power consumption than that in the normal standby mode. For example, in the sleep mode, the output of the LED 41 may be reduced than that in the normal standby mode. For the sleep mode, the technique thereof is not limited as long as the power consumption can be reduced than that in the normal standby mode.

The operation input device according to the present embodiment sets a first threshold and a second threshold for a detection value of a detection unit. In a case where the detection value of the detection unit is less than the second threshold, the operation input device stands by in a sleep mode in which a power consumption is reduced as compared to a normal standby mode, and therefore, the power consumption can be reduced. Moreover, in a case where the detection value of the detection unit is equal to or greater than the second threshold, the operation input device stands by in the normal standby mode. In a case where the detection value is equal to or greater than the first threshold, the operation input device detects input operation to cause operation equipment to perform operation. Thus, in a case where a detection target object approaches the detection unit to a certain extent, further approaching of the detection target object to the detection unit can be promptly sensed. Thus, in a case where the detection target object approaches the detection unit and the input operation is actually performed, the operation equipment can promptly perform operation. As a result, a time lag in operation of the equipment in response to the input operation can be reduced while the power consumption can be reduced.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An operation input device comprising:
a detection unit configured to sense a detection value changing according to a distance to a detection target object; and
a controller configured to detect input operation in a case where the detection value is equal to or greater than a first threshold indicating that a distance between the detection target object and the detection unit is equal to or shorter than a first distance, wherein
the controller stands by in a sleep mode in which a power consumption is reduced as compared to a normal standby mode in a case where the detection value is less than a second threshold, which is smaller than the first threshold, as a threshold indicating that the distance between the detection target object and the detection unit is equal to or shorter than a second distance longer than the first distance, and stands by in the normal standby mode in a case where the detection value is equal to or greater than the second threshold.

2. The operation input device according to claim 1, wherein
the detection unit is a capacitance sensor, and
the detection value is an electric field intensity sensed by the sensor.

3. The operation input device according to claim 1, further comprising:
a projection unit configured to irradiate detection light, wherein
the detection unit is a light receiving unit configured to receive the detection light reflected on the detection target object, and
the detection value is an angle of the detection light reflected on the detection target object.

4. The operation input device according to claim 1, wherein
the controller reduces, in the sleep mode, a frequency of sensing the detection value or a frequency of comparing the detection value with the first and second thresholds as compared to the normal standby mode, thereby reducing the power consumption in the sleep mode than that in the normal standby mode.

5. The operation input device according to claim 2, wherein
the controller reduces, in the sleep mode, a frequency of sensing the detection value or a frequency of comparing the detection value with the first and second thresholds as compared to the normal standby mode, thereby reducing the power consumption in the sleep mode than that in the normal standby mode.

6. The operation input device according to claim 3, wherein
the controller reduces, in the sleep mode, a frequency of sensing the detection value or a frequency of comparing the detection value with the first and second thresholds as compared to the normal standby mode, thereby reducing the power consumption in the sleep mode than that in the normal standby mode.
